(19) United States
(12) Patent Application Publication
(10) Pub. No.: US 2025/0192060 A1
(43) Pub. Date: Jun. 12, 2025

(54) SEMICONDUCTOR PACKAGE

(71) Applicant: Samsung Electronics Co., Ltd., Suwon-si (KR)

(72) Inventor: Eunsu Lee, Suwon-si (KR)

(21) Appl. No.: 18/747,949

(22) Filed: Jun. 19, 2024

(30) Foreign Application Priority Data
Dec. 6, 2023 (KR) 10-2023-0175917

(51) Int. Cl. H01L 23/538; H01L 23/00; H01L 23/31; H01L 23/367; H01L 23/48; H01L 23/498; H01L 25/16; H10B 80/00

(52) U.S. Cl. CPC H01L 23/5385; H01L 23/3107; H01L 23/3157; H01L 23/367; H01L 23/49822; H01L 24/16; H01L 25/162; H01L 23/481; H01L 23/49816; H01L 2224/16227; H10B 80/00

(57) ABSTRACT

A semiconductor package according to example embodiment may include: a lower substrate including a lower wiring layer; an upper substrate disposed on the lower substrate and including an upper wiring layer; a first semiconductor chip having a lower surface disposed between an upper surface of the lower substrate and a lower surface of the upper substrate and electrically connected to the lower wiring layer; a second semiconductor chip disposed on the lower substrate to be spaced apart from the first semiconductor chip in a first direction and electrically connected to the lower wiring layer; and a third semiconductor chip disposed on the upper substrate and electrically connected to the upper wiring layer, wherein the upper substrate may include a through-hole exposing at least a portion of the first semiconductor chip.

### CROSS-REFERENCE TO RELATED APPLICATION(S)

This application claims benefit of priority to Korean Patent Application No. 10-2023-0175917 filed on Dec. 6, 2023, in the Korean Intellectual Property Office, the disclosure of which is incorporated herein by reference in its entirety.

### BACKGROUND

The present disclosure relates to a semiconductor package. More specifically, the present disclosure relates to a semiconductor package having improved integration and excellent heat dissipation characteristics.

Semiconductors are becoming highly integrated and as part of the integration, a system-on-chip (SoC) is continuously being developed. For example, a controller chip including a modem, an RF module, a battery, and other electronic components may be mounted on a package substrate as a system-on-chip. Furthermore, according to the trend for high speed and high performance electronic devices, the operational reliability of the electronic device may be improved when the heat dissipation characteristics of a semiconductor package included in the electronic device are excellent.

### SUMMARY

An aspect of embodiments of the inventive concept is to provide a semiconductor package having improved heat dissipation characteristics while improving the integration of the semiconductor package.

However, the objective of the inventive concept is not limited to the above-described objectives, and may be variously extended without departing from the spirit and domain of the present disclosure.

According to an aspect of the present disclosure, a semiconductor package may include: a lower substrate including a lower wiring layer; an upper substrate disposed on the lower substrate and including an upper wiring layer; a first semiconductor chip with a lower surface disposed between a lower surface of the lower substrate and the upper substrate and electrically connected to the lower wiring layer; a second semiconductor chip disposed on the lower substrate and spaced apart from the first semiconductor chip in a first direction and electrically connected to the lower wiring layer; and a third semiconductor chip disposed on the upper substrate and electrically connected to the upper wiring layer, wherein the upper substrate has a through-hole exposing at least a portion of the first semiconductor chip.

According to an aspect of the present disclosure, a semiconductor package may include: a lower substrate including a first region and a second region spaced apart from the first region in a first direction, and including a lower wiring layer; a first semiconductor chip disposed on the first region and electrically connected to the lower wiring layer; a second semiconductor chip disposed on the second region and electrically connected to the lower wiring layer; an upper substrate including a through-hole exposing at least a portion of an upper surface of the first semiconductor chip disposed on the first region and an upper wiring layer; and a third semiconductor chip disposed on the upper substrate and electrically connected to the upper wiring layer.

According to an aspect of the present disclosure, a semiconductor package may include: a lower substrate including a lower wiring layer; an upper substrate disposed on the lower substrate and including an upper wiring layer; a plurality of electrical connectors disposed between the lower substrate and the upper substrate and electrically connecting the lower wiring layer and the upper wiring layer; a first semiconductor chip disposed at the same level as the plurality of electrical connectors, surrounded by the plurality of electrical connectors, and electrically connected to the lower wiring layer; a second semiconductor chip disposed on the lower substrate to be spaced apart from the first semiconductor chip in a first direction and electrically connected to the lower wiring layer; and a third semiconductor chip disposed on the upper substrate and electrically connected to the upper wiring layer, wherein an upper surface of the first semiconductor chip may be at least partially exposed through an opening region of the upper substrate.

A semiconductor package according to example embodiments of the present disclosure may include a semiconductor chip overlapping a memory chip, apart from the memory chip and a controller chip, and an upper substrate exposing at least a portion of the semiconductor chip. Accordingly, a semiconductor package having improved reliability may be provided by increasing the integration of the semiconductor package and improving heat dissipation characteristics.

Advantages and effects of the present application are not limited to the foregoing content and may be variously extended without departing from the spirit and domain of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor package according to an example embodiment of the present disclosure;

FIG. 2A is a cross-sectional view illustrating an example embodiment taken along the line A-A′ of FIG. 1;

FIG. 2B is a cross-sectional view illustrating an example embodiment taken along the line A-A′ of FIG. 1;

FIG. 2C is a cross-sectional view illustrating an example embodiment taken along the line A-A′ of FIG. 1;

FIG. 2D is a cross-sectional view illustrating an example embodiment taken along the line A-A′ of FIG. 1;

FIG. 2E is a cross-sectional view illustrating an example embodiment taken along the line A-A′ of FIG. 1;

FIG. 3A is a cross-sectional view illustrating an example embodiment taken along the line B-B′ of FIG. 1;

FIG. 3B is a cross-sectional view illustrating an example embodiment taken along the line B-B′ of FIG. 1;

FIG. 4 is a plan view illustrating a semiconductor package according to another example embodiment;

FIG. 5 is a plan view illustrating a semiconductor package according to another example embodiment; and

FIG. 6 is a cross-sectional view illustrating a state of a semiconductor package in accordance with an example embodiment of a method of manufacturing the semiconductor package of FIG. 2A.

FIG. 7 is a cross-sectional view illustrating a state of a semiconductor package in accordance with an example embodiment of a method of manufacturing the semiconductor package of FIG. 2A.

FIG. 8 is a cross-sectional view illustrating a state of a semiconductor package in accordance with an example embodiment of a method of manufacturing the semiconductor package of FIG. 2A.

FIG. 9 is a cross-sectional view illustrating a state of a semiconductor package in accordance with an example embodiment of a method of manufacturing the semiconductor package of FIG. 2A.

FIG. 10 is a cross-sectional view illustrating a state of a semiconductor package in accordance with an example embodiment of a method of manufacturing the semiconductor package of FIG. 2A.

FIG. 11 is a cross-sectional view illustrating a state of a semiconductor package in accordance with an example embodiment of a method of manufacturing the semiconductor package of FIG. 2A.

### DETAILED DESCRIPTION

Hereinafter, example embodiments of the present disclosure will be described with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the description, the same reference numerals are used for the same components in the drawings and redundant descriptions for the same components may be omitted. As used herein, the singular forms “a”, “an” and “the” are intended to include the plural forms as well, unless the context clearly indicates otherwise. Similarly, although the specification may describe an item in the plural, unless multiple items are specifically described, there may be a single item in some embodiments. As used herein, the term “and/or” includes any and all combinations of one or more of the associated listed items and may be abbreviated as “/”. When referring to relationships involving plural items, it will be understood that the relationship may be a one-to-one, one-to-many, many-to-one, or many-to-many relationship between items in the plurality. Additionally, in the description, a single reference number may be used to represent all the items of a plurality, and, although a single item may be identified with a reference number, it will be apparent that other items of the plurality are present in the drawings.

Spatially relative terms, such as “beneath,” “below,” “lower,” “above,” “upper,” “top,” “bottom,” and the like, may be used herein for ease of description to describe positional relationships and are given with reference to the orientation shown in the figures. It will be understood that the spatially relative terms encompass different orientations of the device in addition to the orientation depicted in the figures.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

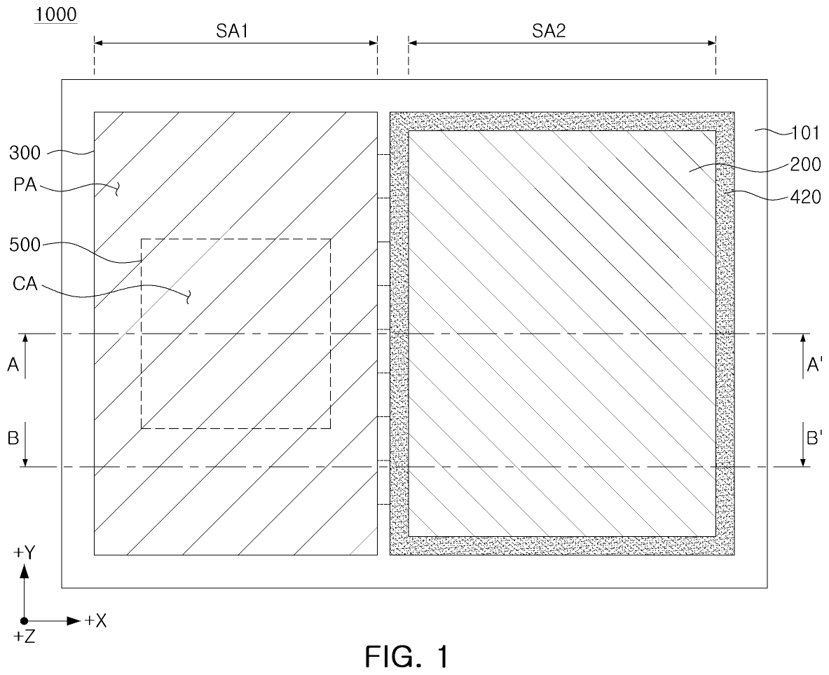

FIG. 1 is a plan view illustrating a semiconductor package according to an example embodiment of the present disclosure.

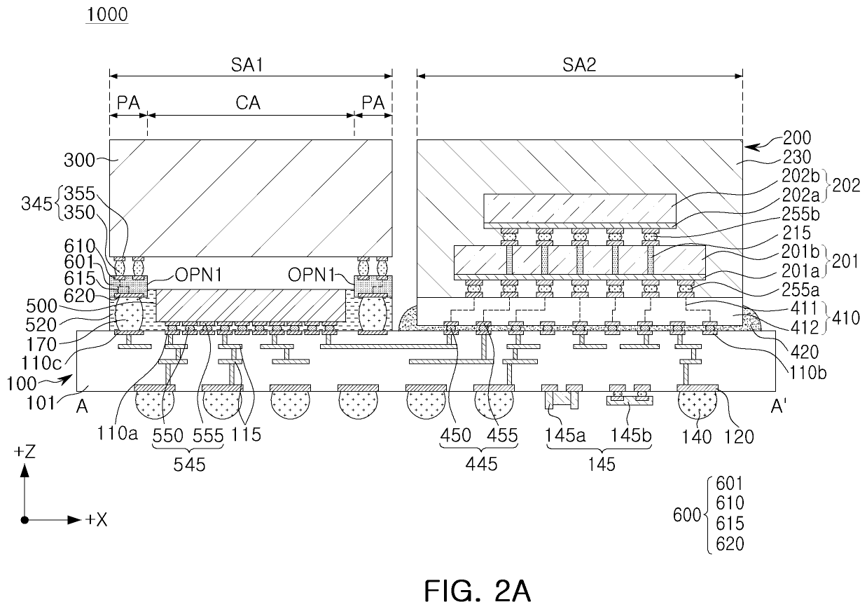

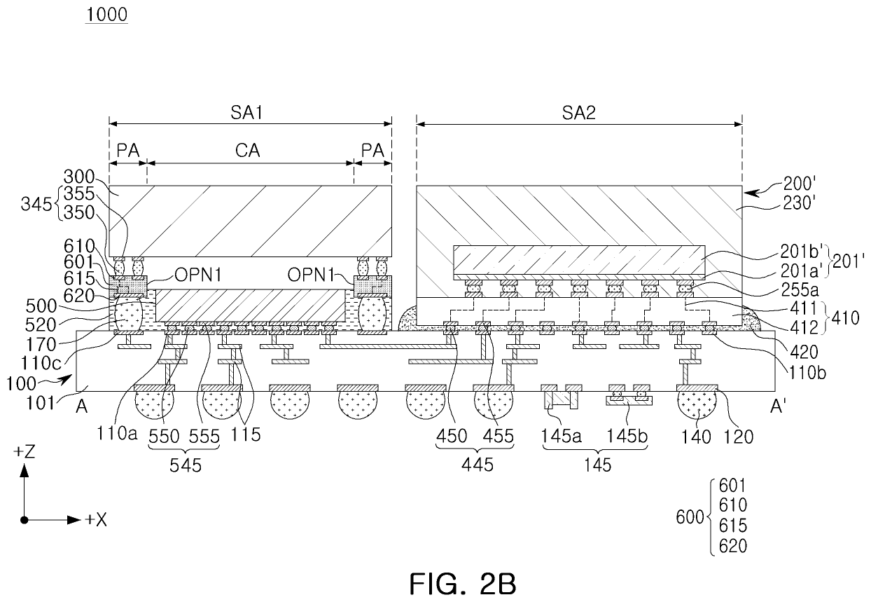

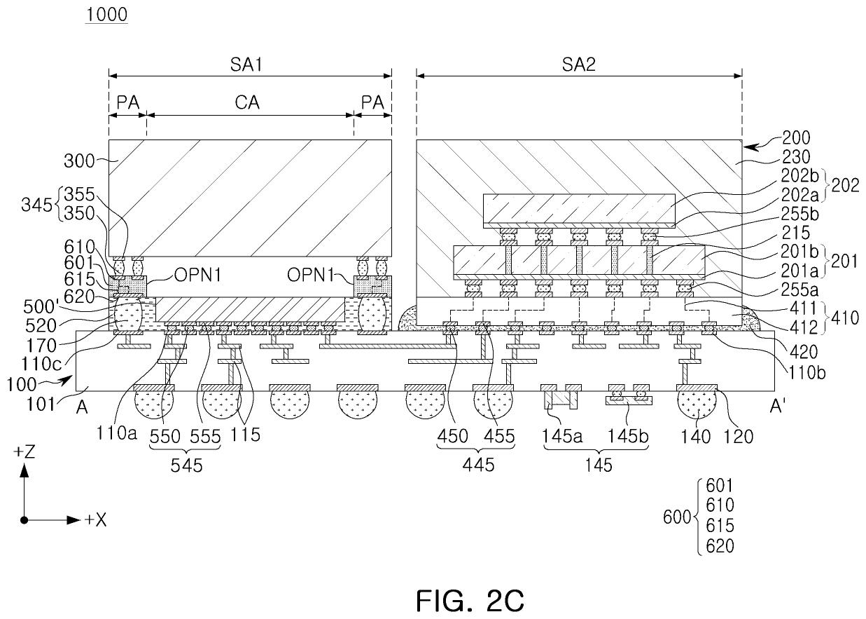

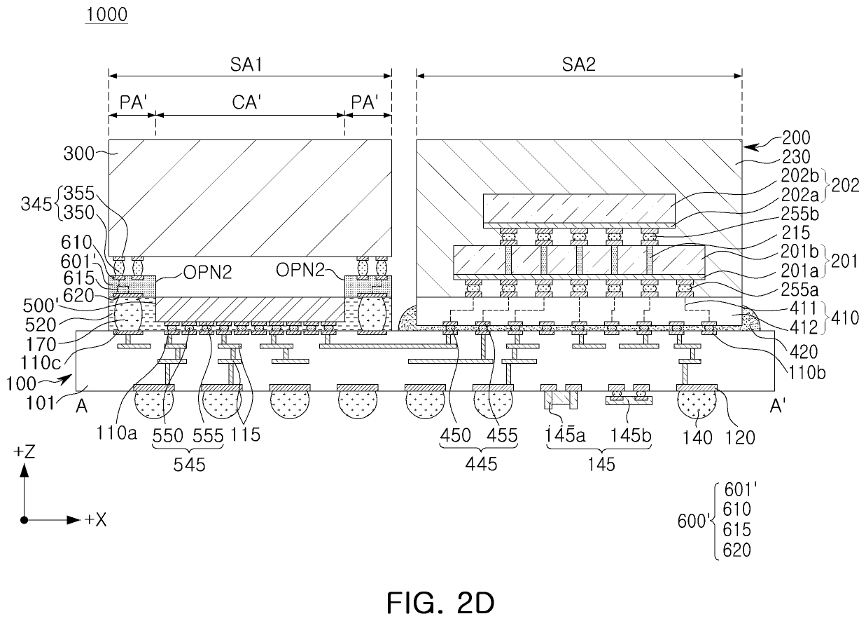

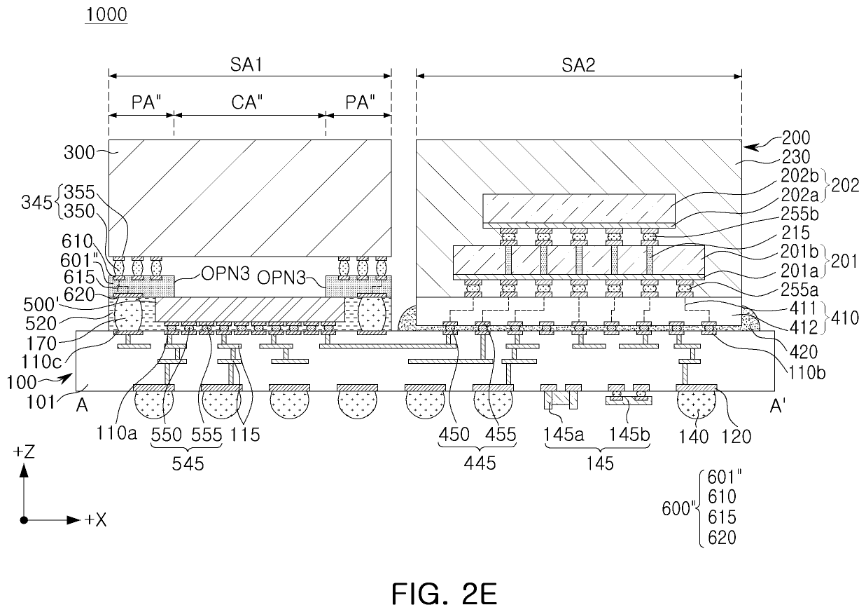

Referring to FIGS. 1 and 2A, a semiconductor package 1000 may include a lower base 100, an upper base 600, a first semiconductor chip 500, a second semiconductor chip 200, a third semiconductor chip 300, and a rewiring structure 410.

In an example embodiment, the lower base 100 (or a package substrate) may include a lower substrate 101, first upper pads 110a, 110b and 110c, first lower pads 120, and a first rewiring circuit 115 electrically connecting the first upper pads 110a, 110b and 110c to the first lower pads 120.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

In an example embodiment, the lower substrate 101 may be a support substrate on which the first semiconductor chip 500 and the second semiconductor chip 200 are mounted, and may be a substrate for a semiconductor package and may include a printed circuit board (PCB), a ceramic substrate, a glass substrate, or a tape wiring substrate. In one example, the lower substrate 101 may include different materials depending on the type of substrate. For example, when the lower substrate 101 is a printed circuit board, the lower substrate 101 may be in a form in which a wiring layer is further stacked on one surface or opposing surfaces of a copper clad laminate. In one example, a solder resist layer may be disposed on a lower surface and an upper surface of the lower substrate 101.

In an example embodiment, the lower substrate 101 may include a first region SA1 and a second region SA2 spaced apart from the first region SA1 in a first direction (+X-direction). In one example, the first region SA1 may be a region in which the first semiconductor chip 500 is mounted. The third semiconductor chip 300 may be disposed on the first semiconductor chip 500 and overlap the first region SA1 in a vertical direction (+Z-direction). The second region SA2 may be a region in which the second semiconductor chip 200 is mounted. In one example, the first semiconductor chip 500 may be disposed to be spaced apart from the second semiconductor chip 200 in the first direction (+X-direction).

In an example embodiment, the first upper pads 110a, 110b and 110c may be disposed on the upper surface of the lower substrate 101. The first upper pads 110a, 110b and 110c may include 1-1 first upper pads 110a, 1-2 first upper pads 110b, and 1-3 first upper pads 110c. In one example, the 1-1 first upper pads 110a and the 1-3 first upper pads 110c may be disposed at the upper surface of the lower substrate 101 corresponding to the first region SA1. In one example, the 1-3 first upper pads 110c may be disposed at the same level as the 1-1 first upper pads 110a, and may surround the 1-1 first upper pads 110a. In one example, the 1-2 upper pads 110b may be disposed on an upper surface of the second region SA2 of the lower substrate 101.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. The same level indicates that items are at the same vertical level relative to a base feature, such as the lower substrate.

In an example embodiment, the first lower pads 120 may be disposed on a lower surface of the lower substrate 101.

In an example embodiment, the first rewiring circuit 115 (or a lower wiring layer) may be embedded in the lower substrate 101 to electrically connect the first upper pads 110a, 110b and 110c and the first lower pads 120.

In an example embodiment, the first upper pads 110a, 110b and 110c, the first lower pads 120, and the first rewiring circuit 115 may form an electrical path from an upper surface to a lower surface of the lower substrate 101. In one example, the first upper pads 110a, 110b and 110c, the first lower pads 120, and the first rewiring circuit 115 may be formed of and/or include a metallic material. The metallic material may include an alloy including at least one metal or at least one metal and at least one or more metals of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C). In one example, the first rewiring circuit 115 may include multilayered rewiring layers and vias connecting the same.

In an example embodiment, the lower base 100 may further include lower connection bumps 140 and passive elements 145. In one example, the lower connection bumps 140 may be disposed on the lower surface of the lower substrate 101 and may be electrically connected to the first lower pads 120. The lower connection bumps 140 may include tin (Sn), indium (In), bismuth (Bi), antimony (Sb), copper (Cu), silver (Ag), zinc (Zn), lead (Pb), or alloys thereof. In one example, the passive elements 145 may be disposed on the lower surface of the lower substrate 101 and may be disposed at the same level as the lower connection bumps 140. In one example, the passive elements 145 may include a capacitor 145a and a resistor 145b.

In an example embodiment, the semiconductor package 1000 may further include first connection patterns 545 and second connection patterns 445. In one example, the first connection patterns 545 may be disposed between the first semiconductor chip 500 and the lower base 100, and may electrically connect the first semiconductor chip 500 and the lower base 100. The second connection patterns 445 may be disposed between the rewiring structure 410 and the lower base 100, and may electrically connect the rewiring structure 410 and the lower base 100.

In an example embodiment, the first semiconductor chip 500 may be disposed on the first region SA1 of the lower substrate 101. The first semiconductor chip 500 may be disposed to overlap the 1-1 first upper pads 110a of the lower substrate 101 in the vertical direction. In one example, the first semiconductor chip 500 may be electrically connected to the first rewiring circuit 115 of the lower substrate 101 through the first connection patterns 545 and the 1-1 first upper pads 110a. In one example, the first connection patterns 545 may include first connection pads 555 and first connection bumps 550. The first connection pads 555 may be disposed on the lower surface of the first semiconductor chip 500. The first connection bumps 550 may be disposed between the first connection pads 555 and the 1-1 first upper pads 110a.

In an example embodiment, the first semiconductor chip 500 may include a communication processor (CP). However, the present disclosure is not limited thereto, and the first semiconductor chip 500 may include a logic chip such as a modem, a central processing unit (CPU), or a graphic processing unit (GPU).

In an example embodiment, the rewiring structure 410 may be disposed on the second region SA2 of the lower substrate 101. The rewiring structure 410 may be disposed to overlap the 1-2 upper pads 110b of the lower substrate 101 in the vertical direction. The rewiring structure 410 may include a single or multi layered wiring layer 411 and an insulating layer 412. When the rewiring structure 410 has a multilayer wiring structure, wirings arranged in different layers may be connected to each other through vertical contacts. In one example, the rewiring structure 410 may be electrically connected to the first rewiring circuit 115 of the lower substrate 101 through the second connection patterns 445 and the 1-2 upper pads 110b. In one example, the second connection patterns 445 may include second connection pads 455 and second connection bumps 450. The second connection pads 455 may be disposed on a lower surface of the rewiring structure 410. The second connection bumps 450 may be disposed between the 1-2 upper pads 110b and the second connection pads 455.

In an example embodiment, the first connection patterns 545 and the second connection patterns 445 may be disposed on the upper surface of the lower substrate 101 and may be disposed at the same level as one another.

In an example embodiment, the second semiconductor chip 200 may be disposed to overlap the second region SA2 of the lower substrate 101 in the vertical direction (e.g., the third direction (+Z-direction)). In one example, the second semiconductor chip 200 may be disposed on the rewiring structure 410. In one example, the second semiconductor chip 200 may include a plurality of semiconductor dies which may include a first die 201 and a second die 202, die connection patterns such as first die connection pattern 225a and second die connection pattern 225b, and an encapsulant 230.

In an example embodiment, the plurality of semiconductor dies 201 and 202 may be sequentially stacked in the vertical direction (+Z-direction) on the rewiring structure 410. The first die 201 and the second die 202 may be sequentially stacked on the rewiring structure 410 in the vertical direction (+Z-direction). Although the number of semiconductor dies stacked is illustrated as two, the present disclosure is not limited thereto, and two or more semiconductor dies may be included.

In an example embodiment, the first die 201 may include a first base substrate 201a, a first circuit layer 201b disposed on the first base substrate 201a, and through-electrodes 215 penetrating through the first circuit layer 201b. The first die 201 may be disposed on the rewiring structure 410 through a first die connection pattern 255a disposed on a lower surface of the first base substrate 201a. The first die 201 may be electrically connected to the rewiring structure 410 through the first die connection pattern 255a.

In an example embodiment, the second die 202 may include a second base substrate 202a and a second circuit layer 202b disposed on the second base substrate 202a. The second die 202 may be disposed on the first die 201 through a second die connection pattern 255b disposed on a lower surface of the second base substrate 202a. The second die 202 may be electrically connected to the first die 201 through the second die connection pattern 255b.

In an example embodiment, the first and second base substrates 201a and 202a may be formed of and/or include a semiconductor element such as silicon (Si) or germanium (Ge), or compound semiconductors such as silicon carbide (SiC), gallium arsenide (GaAs), indium arsenide (InAs), or indium phosphide (InP).

In an example embodiment, each of the first and second circuit layers 201b and 202b may be disposed on active surfaces of the first and second base substrates 201a and 202a and may include an interlayer insulating layer and a wiring structure. In one example, the interlayer insulating layer may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. The interlayer insulating layer may be formed using chemical vapor deposition (CVD), a flowable-CVD process, or a spin coating process. In one example, the wiring structure may be buried in the interlayer insulating layer. The wiring structure may be formed as a multilayered structure including a via and a wiring pattern, each of which may be formed of Aluminum (Al), gold (Au), cobalt (Co), copper (Cu), nickel (Ni), lead (Pb), tantalum (Ta), tellurium (Te), titanium (Ti), tungsten (W), or a combination thereof.

The through-electrodes 215 of the first die 201 may penetrate through the first circuit layer 201b and may electrically connect the first and second die connection patterns 255a and 255b.

In an example embodiment, the encapsulant 230 may surround the plurality of semiconductor dies on the rewiring structure 410.

In an example embodiment, the second semiconductor chip 200 may include a logic chip, a processor chip, or a controller chip. In one example, the second semiconductor chip 200 may include system on chip (SoC), an application processor (AP), a mobile AP, a chip set, or a set of chips. In one example, the second semiconductor chip 200 may be a semiconductor chip that performs a different function from the first semiconductor chip 500.

In an example embodiment, the semiconductor package 1000 may further include an underfill material layer 420 surrounding a side surface of the rewiring structure 410. The underfill material layer 420 may be formed by a capillary underfill (CUF) process, but the present disclosure is not limited thereto. In one example, the underfill material layer 420 may fill at least a portion between the first region SA1 and the second region SA2 on the lower substrate 101.

In an example embodiment, the upper base 600 (or an interposer substrate) may be disposed between the lower base 100 and the third semiconductor chip 300.

In an example embodiment, the upper base 600 may include an upper substrate 601, second upper pads 610a, second lower pads 620a, and a second rewiring circuit 615.

In an example embodiment, the upper substrate 601 may be a support substrate on which the third semiconductor chip 300 is mounted and may be a substrate for a semiconductor package, including a printed circuit board (PCB), a ceramic substrate, a glass substrate, or a tape wiring substrate. In one example, the upper substrate 601 may include features identical to or similar to those of the lower substrate 101. In one example, a height of the upper substrate 601 in the vertical direction (+Z-direction) may be less than a height of the lower substrate 101 in the vertical direction (+Z-direction) (e.g., the thickness of the upper substrate 601 may be less that the thickness of the lower substrate 101).

In an example embodiment, the upper substrate 601 may include a through-hole OPN1 exposing at least a portion (or an upper surface) of the first semiconductor chip 500. The through-hole OPN1 may pass from an upper surface of the upper substrate 601 to a lower surface of the upper substrate 601. All or some (e.g., an upper portion) of the through-hole OPN1 may form an air gap (e.g., a volume that is not filled with another solid material, but may instead be a vacuum or filled with air or other gas (such as gas of the atmosphere surrounding the semiconductor package 1000 during manufacturing of the same)). The top surface of the first semiconductor chip 500 may define a bottom boundary of the air gap. Alternatively, in some embodiments, an additional layer (such as a layer forming a heat sink) may be formed on the top surface of the chip which may define the bottom boundary of the air gap. In one example, the cross-section of the through-hole OPN1 may be a closed curve (e.g., a wall of the through-hole forms an enclosed shape in the horizontal direction). The upper substrate 601 may have a ring-type shape (e.g., the upper substrate may have an annulus shape which may be a square annulus, rectangular annulus, or circular annulus). The through-hole OPN1 may have a circular, square, rectangular, or other enclosed horizontal cross-section. In one example, the through-hole OPN1 may correspond to a shape of an upper surface of the first semiconductor chip 500. For example, when the upper surface of the first semiconductor chip 500 has a ‘square’ shape, the through-hole OPN1 may have a ‘square’ shape. From a top down perspective, the boundary of the through-hole OPN1 and the boundary of the semiconductor chip 500 may be conformal such that the horizontal distance between these two boundaries remains substantially constant. However, the present disclosure is not limited thereto. The center portions of the through-hole OPN1 and the semiconductor chip 500 may overlap (e.g., the through-hole OPN1 and the semiconductor chip 500 may be concentric).

In an example embodiment, the upper substrate 601 may include a central region CA corresponding to the through-hole OPN1 and a peripheral region PA surrounding the central region CA.

In an example embodiment, a width of the through-hole OPN1 of the upper substrate 601 in the first direction (+X-direction) may be larger than a width of the first semiconductor chip 500 in the first direction (+X-direction). In one example, a portion of the first semiconductor chip 500 may be accommodated in the through-hole OPN1 of the upper substrate 601 (e.g., a portion of the first semiconductor chip 500 may be positioned within the through-hole OPN1 of the upper substrate 601). In one example, a separation space may be formed in a horizontal direction (+X-direction) between the upper substrate 601 and the first semiconductor chip 500. In one example, the through-hole OPN1 of the upper substrate 601 may expose the entire upper surface of the first semiconductor chip 500.

In an example embodiment, the first semiconductor chip 500 may overlap the central region CA of the upper substrate 601 in the vertical direction (+Z-direction) and may not overlap the peripheral region PA in the vertical direction (+Z-direction).

In an example embodiment, the upper surface of the first semiconductor chip 500 may be disposed at a lower level than an upper surface of the upper substrate 601. In another example, the upper surface of the first semiconductor chip 500 may be disposed at the same level as the upper surface of the upper substrate 601. In another example, the upper surface of the first semiconductor chip 500 may be disposed at a higher level than the upper surface of the upper substrate 601. In this case, the first semiconductor chip 500 may penetrate completely through the through-hole OPN1 of the upper substrate 601.

In an example embodiment, the second upper pads 610 and the second lower pads 620 may be disposed in the peripheral region PA of the upper substrate 601. In one example, the second upper pads 610 may be disposed on the upper surface of the upper substrate 601. The second lower pads 620 may be disposed on a lower surface of the upper substrate 601. In one example, the second upper pads 610 and the second lower pad 620s may not overlap the first semiconductor chip 500 in the vertical direction (+Z-direction).

In an example embodiment, the second rewiring circuit 615 (or an upper wiring layer) may be buried in the upper substrate 601 and may electrically connect the second upper pads 610 and the second lower pads 620.

In an example embodiment, the semiconductor package 1000 may further include electrical connectors 170 and an encapsulant 520 disposed between the lower base 100 and the upper base 600.

In an example embodiment, the electrical connectors 170 may electrically connect the first rewiring circuit 115 of the lower substrate 101 and a second rewiring circuit 615 of the upper substrate 601. In one example, an electrical connector 170 may be a connection bump disposed between the lower substrate 101 and the upper substrate 601. In one example, the electrical connectors 170 may be disposed between the 1-3 upper pads 110c and the second lower pads 620. In one example, the electrical connectors 170 may overlap the peripheral region PA of the upper substrate 601 in the vertical direction (+Z-direction).

In an example embodiment, the electrical connectors 170 may be disposed at the same level as the first semiconductor chip 500, and may surround the first semiconductor chip 500.

In an example embodiment, a height of the electrical connectors 170 in the vertical direction (+Z-direction) may be lower than a height of the first semiconductor chip 500 in the vertical direction (+Z-direction) (e.g., a length of a connector 170 in the +Z-direction may be less than the thickness of the first semiconductor chip). As a portion of the first semiconductor chip 500 is accommodated in the through-hole OPN1 of the upper substrate 601, the vertical level of an upper surface of the first semiconductor chip 500 may be higher than the vertical level of an upper surface of the electrical connector 170 that is disposed between the lower substrate 101 and the upper substrate 601, relative to the lower substrate 101. The upper surface of the first semiconductor chip 500 may be disposed at a level between the lower surface of the upper substrate 601 and the upper surface of the upper substrate. The lower surface of the first semiconductor chip 500 may be disposed between the upper surface of the lower substrate 101 and the lower surface of the upper substrate.

In an example embodiment, an encapsulant 520 may fill a space between the lower substrate 101 and the upper substrate 601 and may encapsulate a side surface of the electrical connectors 170 and a side surface of the first semiconductor chip 500. In one example, an upper surface of the encapsulant 520 may be disposed at the same level as the upper surface of the first semiconductor chip 500. The encapsulant 520 may not cover the upper surface of the first semiconductor chip 500. In one example, when at least a portion of the first semiconductor chip 500 is accommodated in the through-hole OPN1, the encapsulant 520 may partially fill the through-hole OPN1.

In an example embodiment, the encapsulant 520 may be formed of and/or include a thermosetting resin such as an epoxy resin, a thermoplastic resin such as polyimide, or Prepreg including an inorganic filler or/and a glass fiber, ABF, FR-4, BT, and EMC. The encapsulant 520 may have a molded underfill (MUF) structure, but the present disclosure is not limited thereto. According to an example embodiment, the encapsulant 520 may have a capillary underfill (CUF) structure.

In an example embodiment, the semiconductor package 1000 may further include third connection patterns 345. The third connection patterns 345 may be disposed between the upper base 600 and the third semiconductor chip 300 to electrically connect the upper base 600 and the third semiconductor chip 300.

In an example embodiment, the third semiconductor chip 300 may be disposed on the upper base 600. The third semiconductor chip 300 may be electrically connected to the second rewiring circuit 615 of the upper base 600 through the third connection patterns 345 and the second upper pads 610. In one example, the third connection patterns 345 may include third connection bumps 350 and a third connection pads 355. The third connection pads 355 may be disposed on a lower surface of the third semiconductor chip 300. The third connection bumps 350 may be disposed between the third connection pads 355 and the second upper pads 610 of the upper base 600.

In an example embodiment, the third connection patterns 345 and the electrical connectors 170 may overlap the peripheral region PA of the upper substrate 601 in the vertical direction. In one example, the third connection patterns 345 and the electrical connectors 170 may not overlap the first semiconductor chip 500 in the vertical direction.

In an example embodiment, the third semiconductor chip 300 may overlap the first semiconductor chip 500 and the upper base 600 in the vertical direction (+Z-direction). In one example, the third semiconductor chip 300 may cover the first region SA1 of the lower substrate 101.

In an example embodiment, the third semiconductor chip 300 may include a memory chip. For example, the third semiconductor chip 300 may include a volatile memory chip such as a random access memory (RAM), a dynamic RAM (DRAM), or a static RAM (SRAM). However, the third semiconductor chip 300 is not limited to the volatile memory chip and may include a storage memory chip such as a non-volatile memory chip.

The semiconductor package 1000 according to embodiments of the present disclosure may include the upper substrate 601 including a through-hole OPN1 exposing at least a portion of the first semiconductor chip 500. Accordingly, heat generated from the first semiconductor chip 500 may be easily dissipated through the through-hole OPN1 formed in the upper substrate 601, so that the semiconductor package 1000 may secure excellent heat dissipation characteristics.

FIG. 2B is a cross-sectional view illustrating another example embodiment taken along the line A-A′ in FIG. 1.

Among the remaining components excluding a second semiconductor chip 200′ illustrated in FIG. 2B, overlapping descriptions of components that are identical to or correspond to components illustrated in FIG. 2A will be omitted.

Referring to FIG. 2B, the second semiconductor chip 200′ may include a single-layer semiconductor die. In one example, the second semiconductor chip 200′ may include a semiconductor die 201′ and an encapsulant 230′. In one example, semiconductor die 201′ may be disposed on the rewiring structure 410. In one example, the semiconductor die 201′ may be disposed on the rewiring structure 410 as a single semiconductor die. The semiconductor die 201′ may include a base substrate 201a′ and a circuit layer 201b′ disposed on the base substrate 201a′. In one example, the encapsulant 230′ may surround the semiconductor die 201′ on the rewiring structure 410. FIG. 2C is a cross-sectional view illustrating another example embodiment taken along the line A-A′ in FIG. 1.

Among the remaining components excluding a first semiconductor chip 500′ illustrated in FIG. 2C, overlapping descriptions of components that are identical to or correspond to components illustrated in FIG. 2A may be omitted.

Referring to FIG. 2C, the first semiconductor chip 500′ may not be accommodated in the through-hole OPN1 of the upper substrate 601. In one example, an upper surface of the first semiconductor chip 500′ may be disposed at the same level as the lower surface of the upper substrate 601. In another example, the upper surface of the first semiconductor chip 500′ may be disposed at a lower level than the lower surface of the upper substrate 601.

In an example embodiment, a height of the first semiconductor chip 500′ in the vertical direction (+Z-direction) may be equal to or less than the height of the electrical connector 170 in the vertical direction (+Z-direction).

In an example embodiment, an encapsulant 520 may fill a space between a lower substrate 101 and the upper substrate 601, and may encapsulate a side surface of the electrical connectors 170 and a side surface of the first semiconductor chip 500′. In one example, an upper surface of the encapsulant 520 may be disposed at the same level as an upper surface of the first semiconductor chip 500′. In one example, the encapsulant 520 may not cover an upper surface of the first semiconductor chip 500′. The upper surface of the encapsulant 520 that encapsulates the side surface of the electrical connector 170 and the side surface of the first semiconductor chip 500′ may be disposed at the same level as the lower surface of the upper substrate 601.

In an example embodiment, the through-hole OPN1 of the upper substrate 601 may be configured so that a width thereof in the horizontal direction (+X-direction) may be larger than a width of the first semiconductor chip 500′ in the horizontal direction (+X-direction).

FIG. 2D is a cross-sectional view illustrating another example embodiment taken along the line A-A′ in FIG. 1.

Among the remaining components excluding a first semiconductor chip 500′ and an upper base 600′ illustrated in FIG. 2D, overlapping descriptions of components that are identical to or correspond to components illustrated in FIG. 2A may be omitted.

Referring to FIG. 2D, the upper base 600′ (or an interposer substrate) may be disposed above the lower base 100. The upper base 600′ may include an upper substrate 601′, second upper pads 610, second lower pads 620, and a second rewiring circuit 615.

In an example embodiment, the upper substrate 601′ may include a through-hole OPN2 exposing the upper surface of the first semiconductor chip 500′. In one example, the through-hole OPN2 may include a closed curve. The through-hole OPN2 may correspond to a shape of the upper surface of the first semiconductor chip 500′.

In an example embodiment, the upper substrate 601′ may include a central region CA′ corresponding to the through-hole OPN2 and a peripheral region PA′ surrounding the central region CA′. The first semiconductor chip 500′ may overlap the central region CA′ of the upper substrate 601′ in the vertical direction, and may not overlap the peripheral region PA′. In one example, the central region CA′ may correspond to the upper surface of the first semiconductor chip 500′.

In an example embodiment, a width of the through-hole OPN2 of the upper substrate 601′ in the first direction (+X-direction) may correspond to a width of the first semiconductor chip 500′ in the first direction (or a horizontal direction) (+X-direction). In one example, the width of the through-hole OPN2 of the upper substrate 601′ in the first direction (+X-direction) may be substantially equal to a width of the first semiconductor chip 500′ in the first direction (or a horizontal direction) (+X-direction). In one example, the through-hole OPN2 of the upper substrate 601′ may expose an entire area of the upper surface of the first semiconductor chip 500′.

In an example embodiment, the first semiconductor chip 500′ may not be accommodated in the through-hole OPN2 of the upper substrate 601′.

In an example embodiment, the height of the first semiconductor chip 500′ in the vertical direction (+Z-direction) may be equal to or less than the height of the electrical connector 170 in the vertical direction (+Z-direction).

In an example embodiment, the second upper pads 610 and the second lower pads 620 may be disposed in the peripheral region PA′ of the upper substrate 601′. In one example, the second upper pads 610 may be disposed on an upper surface of the upper substrate 601′. The second lower pads 620 may be disposed on a lower surface of the upper substrate 601′. In one example, the second upper pads 610 and the second lower pads 620 may not overlap the first semiconductor chip 500′ in the vertical direction (+Z-direction).

FIG. 2E is a cross-sectional view illustrating another example embodiment taken along the line A-A′ in FIG. 1.

Among the remaining components excluding a first semiconductor chip 500′ and an upper base 600″ illustrated in FIG. 2E, overlapping description of components that are identical to or correspond to the components illustrated in FIG. 2A may be omitted.

In an example embodiment, the upper base 600″ (or an interposer substrate) may be disposed on a lower base 100 and the first semiconductor chip 500′. The upper base 600″ may include an upper substrate 601″, second upper pads 610, second lower pads 620, and a second rewiring circuit 615.

In an example embodiment, the upper substrate 601″ may be a support substrate on which the third semiconductor chip 300 is mounted.

In an example embodiment, the upper substrate 601″ may include a through-hole OPN3 exposing a portion of an upper surface of the first semiconductor chip 500′.

In an example embodiment, the upper substrate 601″ may include a central region CA″ corresponding to the through-hole OPN3 and a peripheral region PA″ surrounding the central region CA″. In one example, the first semiconductor chip 500′ may overlap the central region CA″ and a portion of the peripheral region PA″ adjacent to the central region CA″ in the vertical direction (+Z-direction).

In an example embodiment, a width of the through-hole OPN3 of the upper substrate 601″ in the first direction (+X-direction) may be smaller than a width of the first semiconductor chip 500′ in the first direction (or a horizontal direction) (+X-direction). In one example, the upper substrate 601″ may expose a portion of the upper surface of the first semiconductor chip 500′ through the through-hole OPN3. The remaining region of the upper surface of the first semiconductor chip 500′, excluding a region exposed through the through-hole OPN3, may be covered by the upper substrate 601″.

In an example embodiment, the upper surface of the first semiconductor chip 500′ may be disposed at the same level as a lower surface of the upper substrate 601.

In an example embodiment, an encapsulant 520 may fill a space between an upper surface of the lower substrate 101 and a lower surface of the upper substrate 601″, and may encapsulate a side surface of the electrical connector 170 and a side surface of the first semiconductor chip 500′.

In an example embodiment, second upper pads 610 and second lower pads 620 may be disposed in the peripheral region PA″ of the upper substrate 601″. In one example, the second upper pads 610 may be disposed on an upper surface of the upper substrate 601″. The second lower pads 620 may be disposed on the lower surface of the upper substrate 601″.

In an example embodiment, the second upper pads 610 and the third connection patterns 345 disposed in a region adjacent to the central region CA″ of the peripheral region PA″ of the upper substrate 601″ may overlap the first semiconductor chip 500′ in the vertical direction (+Z-direction).

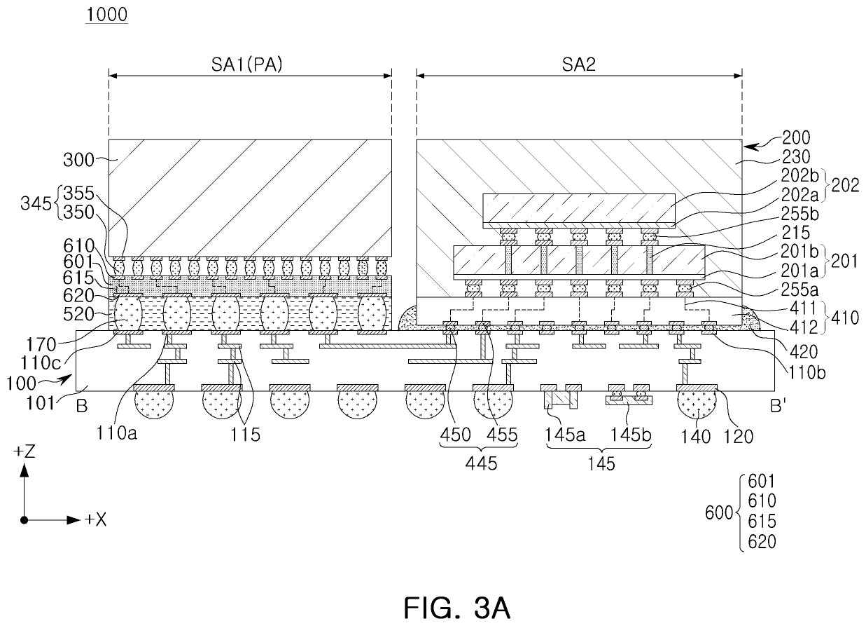

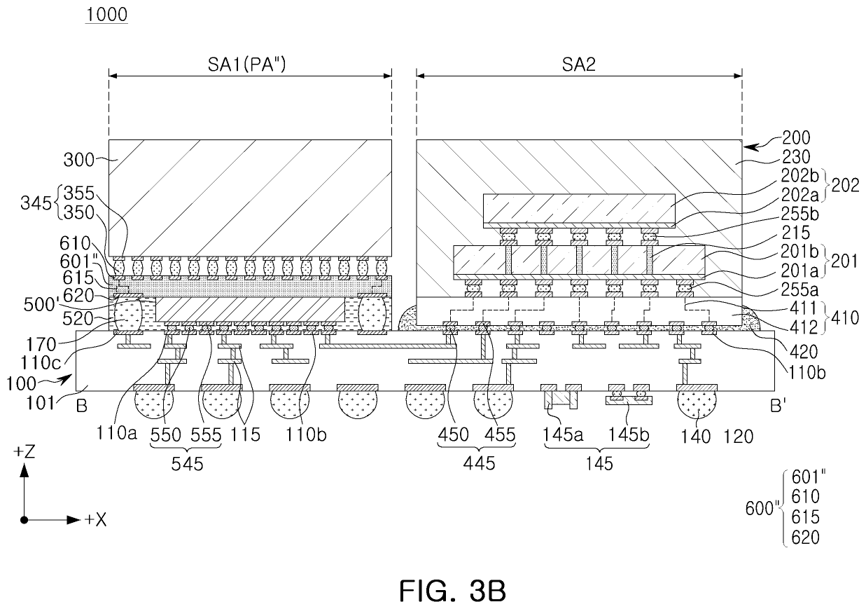

FIG. 3A is a cross-sectional view illustrating an example embodiment taken along line B-B′ in FIG. 1.

Referring to FIG. 3A, a first semiconductor chip (e.g., the first semiconductor chip 500 in FIG. 2A or the first semiconductor chip 500′ in FIG. 2B) may not be disposed in a lower portion of a peripheral region PA of an upper substrate 601.

An electrical connector 170 disposed in the lower portion of the peripheral region PA of the upper substrate 601 may overlap third connection patterns 345 disposed in an upper portion of the peripheral region PA in the vertical direction (+Z-direction).

FIG. 3B is a cross-sectional view illustrating another example embodiment taken along line B-B′ in FIG. 1.

Referring to FIG. 3B, a first semiconductor chip (e.g., the first semiconductor chip 500′ of FIG. 2D) may be disposed at a lower portion of the peripheral region PA″ of the upper substrate 601″.

In an example embodiment, a region adjacent to a central region (e.g., the central region CA″ in FIG. 2D) of the peripheral region PA″ of the upper substrate 601″ may overlap the first semiconductor chip 500′ in the vertical direction (+Z-direction). The first semiconductor chip 500′ disposed at the lower portion of the peripheral region PA″ of the upper substrate 601″ may overlap the third connection patterns 345.

In an example embodiment, the first semiconductor chip 500′ disposed at a lower portion of the peripheral region PA″ of the upper substrate 601″ may be in contact with a lower surface of the upper substrate 601″. However, the present disclosure is not limited thereto, and the first semiconductor chip 500′ may be disposed at the lower portion of the peripheral region PA″ to be spaced apart from the upper substrate 601″.

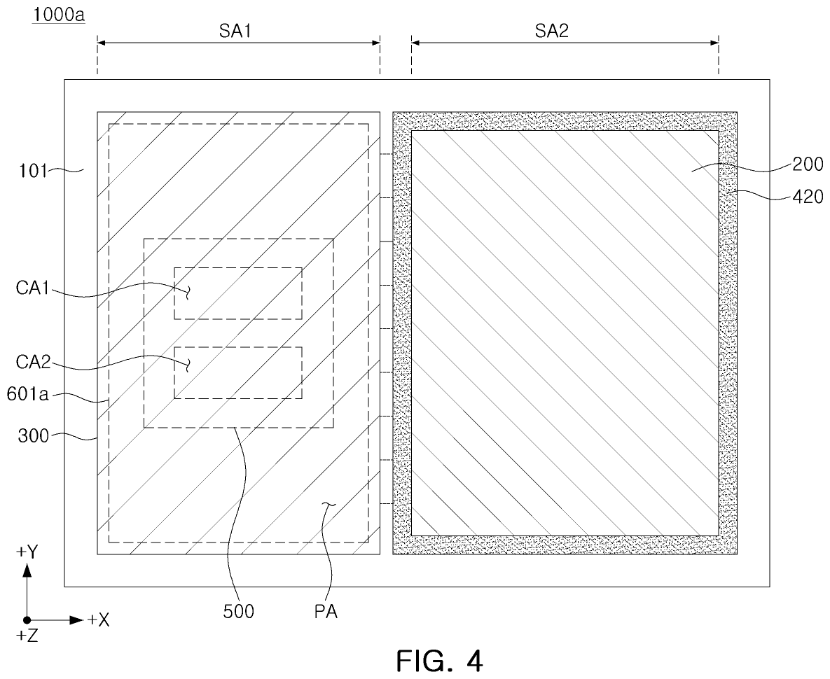

FIG. 4 is a plan view illustrating a semiconductor package according to another example embodiment.

Referring to FIG. 4, among the remaining components excluding an upper substrate 601a illustrated in FIG. 4, overlapping descriptions of components that are identical to or which correspond to the components illustrated in FIG. 2A may be omitted.

A semiconductor package 1000a may include a lower substrate 101, an upper substrate 601a, a first semiconductor chip 500, a second semiconductor chip 200, and a third semiconductor chip 300.

The upper substrate 601a may include a plurality of through-holes exposing a portion of the first semiconductor chip 500. A portion of the first semiconductor chip 500 may be exposed through the plurality of through-holes. In one example, the upper substrate 601a may include central regions CA1 and CA2 corresponding to the plurality of through-holes, and a peripheral region PA surrounding the central regions CA1 and CA2.

In an example embodiment, the plurality of through-holes may be spaced apart from each other in a second direction (+Y-direction). Accordingly, the central regions CA1 and CA2 may be disposed to be spaced apart from each other in the second direction (+Y-direction). However, the present invention is not limited thereto, and the plurality of through-holes may be spaced apart from each other in the first direction (+X-direction). The central regions CA1 and CA2 may be disposed to be spaced apart from each other in the first direction (+X-direction).

In an example embodiment, the peripheral region PA adjacent to the central regions CA1 and CA2 may overlap the first semiconductor chip 500.

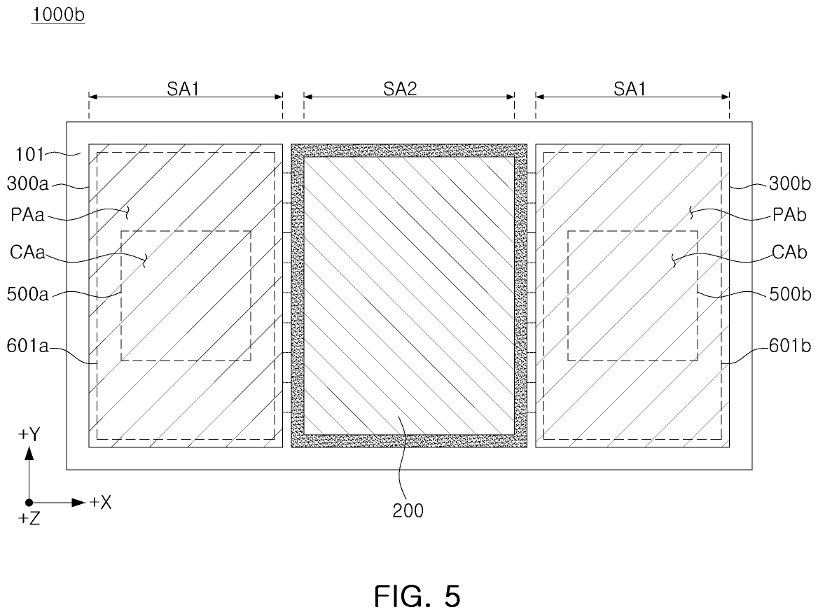

FIG. 5 is a plan view illustrating a semiconductor package according to another example embodiment.

Referring to FIG. 5, a semiconductor package 1000b may include a lower substrate 101a, upper substrates 601a and 601b, a plurality of first semiconductor chips 500a and 500b, a plurality of third semiconductor chips 300a and 300b, and a second semiconductor chip 200. In one example, the plurality of first semiconductor chips 500a and 500b may include a 1-1 semiconductor chip 500a, and a 1-2 semiconductor chip 500b spaced apart from the 1-1 semiconductor chip 500a in the first direction (+X-direction). The plurality of third semiconductor chips 300a and 300b may include a 3-1 semiconductor chip 300a, and a 3-2 semiconductor chip 300b spaced apart from the 3-1 semiconductor chip 300a in the first direction (+X-direction).

In an example embodiment, the lower substrate 101 may include a first region SA1, a second region SA2, and a third region SA3, which are disposed to be sequentially spaced apart from each other in the first direction (+X-direction). In one example, the first region SA1 and the third region SA3 may be symmetrical to each other with the second region SA2 interposed therebetween.

In an example embodiment, the first region SA1 may be a region in which the 1-1 semiconductor chip 500a is mounted. The 3-1 semiconductor chip 300a may be disposed on the 1-1 semiconductor chip 500a to vertically overlap the first region SA1. In one example, the third region SA3 may be a region in which the 1-2 semiconductor chip 500b is mounted. The 3-2 semiconductor chip 300b may be disposed on the 1-2 semiconductor chip 500b to vertically overlap the third region SA3. In one example, the second region SA2 may be a region disposed between the first region SA1 and the third region SA3, in which the second semiconductor chip 200 is mounted.

In an example embodiment, the upper substrate 601a may be a support substrate on which the third semiconductor chip 300a is mounted. The upper substrate 601a may include a through-hole exposing at least a portion of the 1-1 semiconductor chip 500a. The upper substrate 601a may include a central region CAa corresponding to the through-hole of the upper substrate 601a and a peripheral region PAa surrounding the central region CAa.

In an example embodiment, the upper substrate 601b may be a support substrate on which the third semiconductor chip 300b is mounted. The upper substrate 601b may include a through-hole exposing at least a portion of the 1-2 semiconductor chip 500b. The upper substrate 601b may include a central region CAb corresponding to the through-hole of the upper substrate 601b, and a peripheral region PAb surrounding the central region CAb.

The semiconductor package 1000b is illustrated as including two first semiconductor chips 500a and 500b and two third semiconductor chips 300a and 300b, but the present disclosure is not limited thereto. For example, the semiconductor package 1000b may include four or more first and third semiconductor chips.

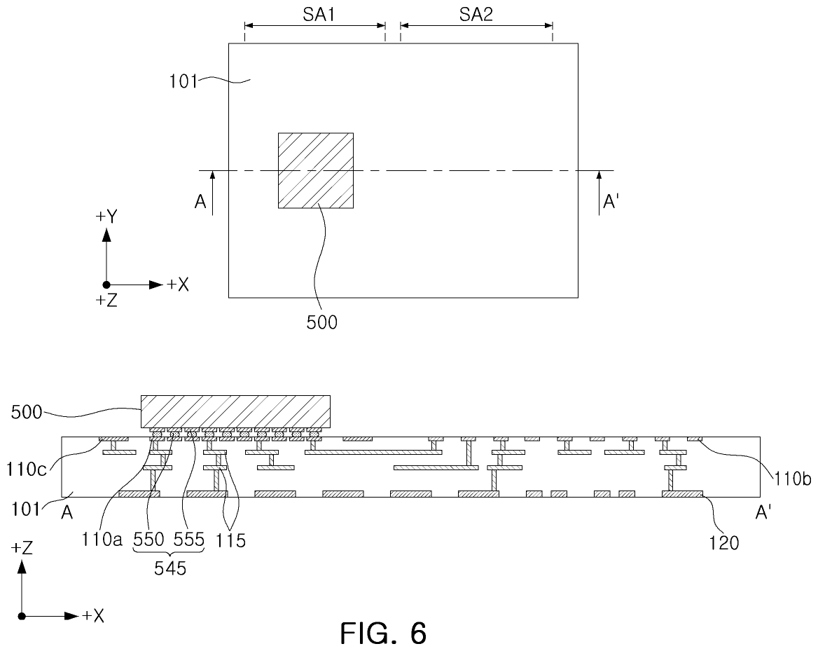

FIGS. 6 to 11 are views illustrating an example embodiment of a method of manufacturing the semiconductor package of FIG. 2A. In the following description, “forming” an item may refer to performing a manufacturing process to generate the item or may refer to positioning a previously manufactured item to form the item in the method.

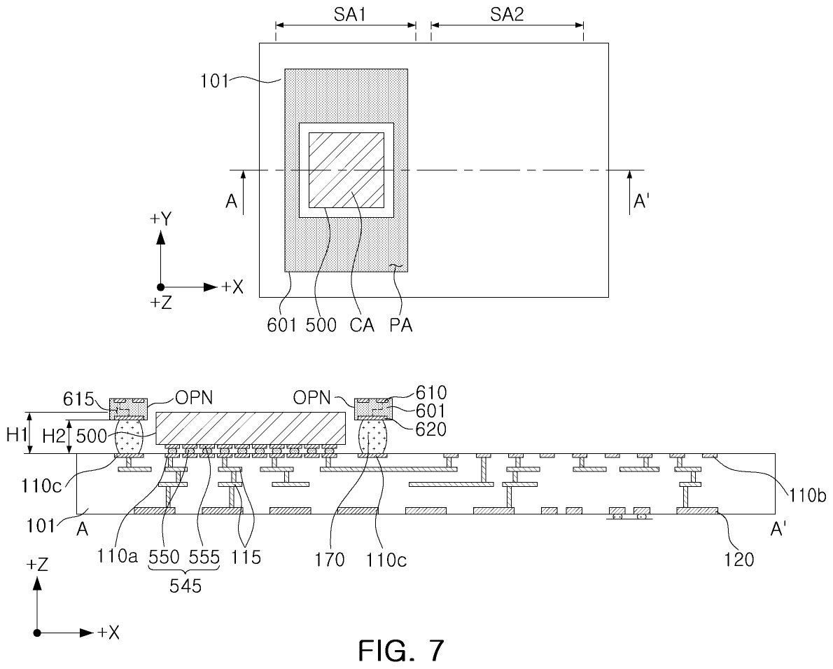

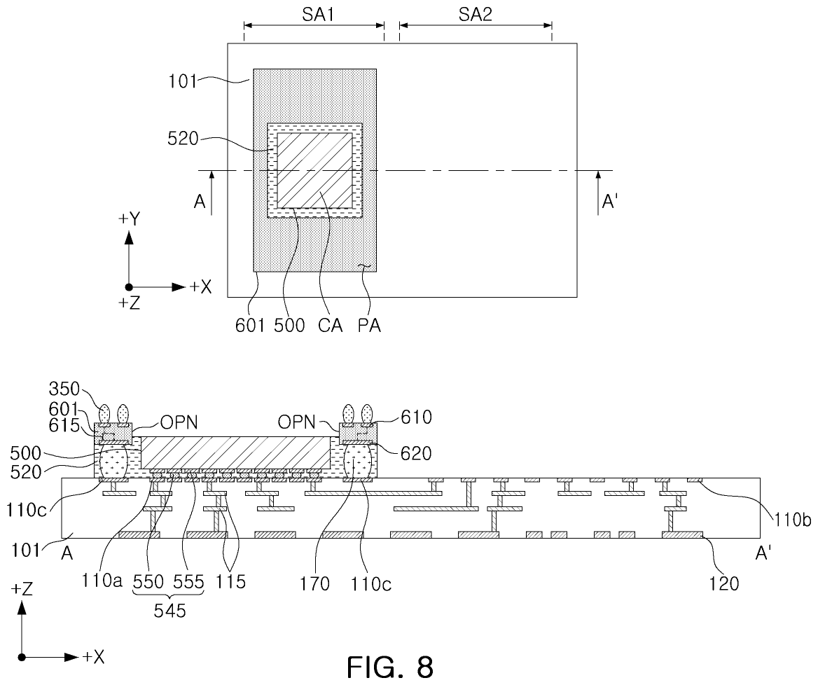

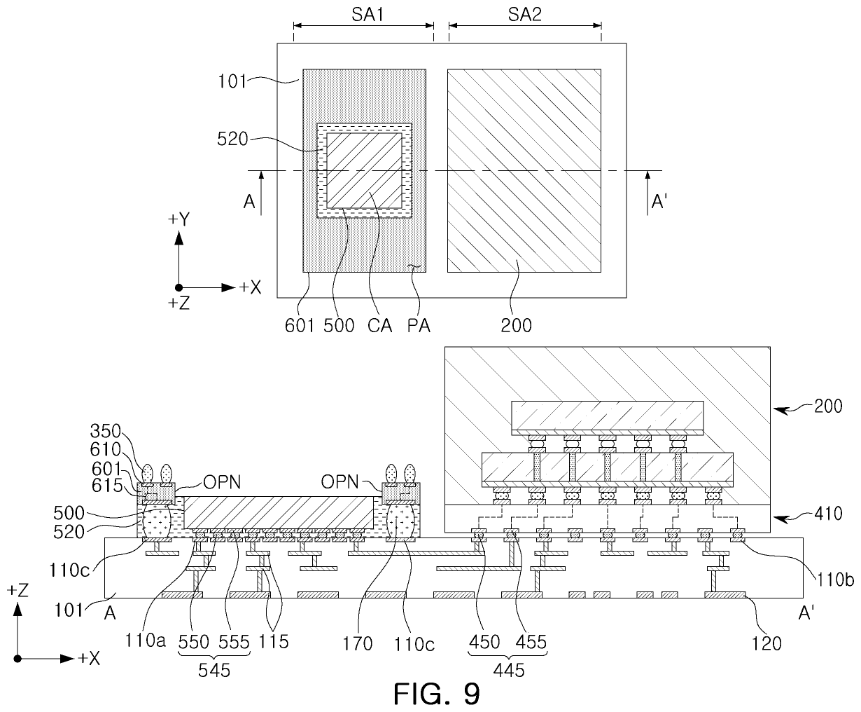

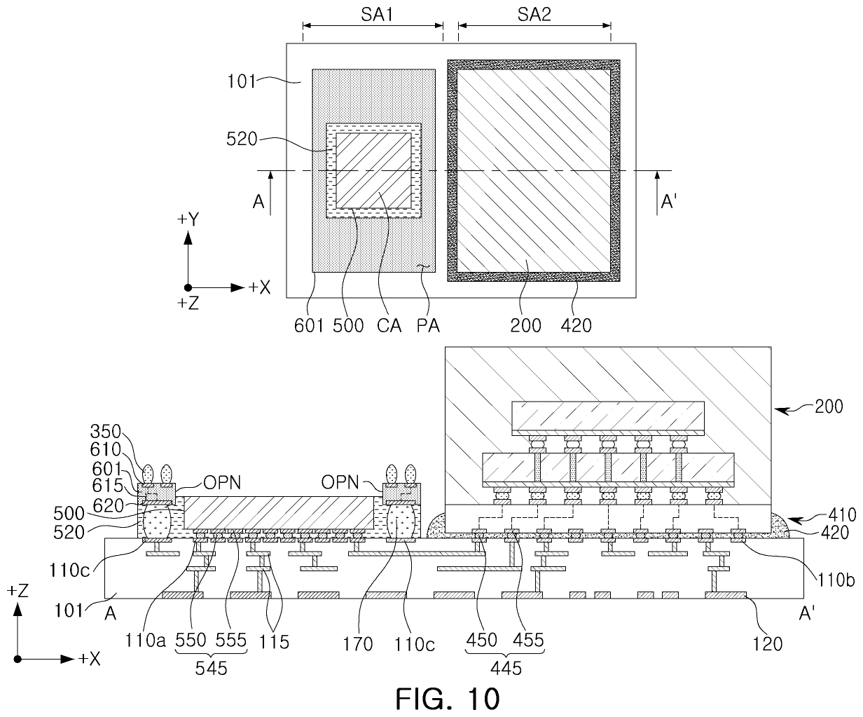

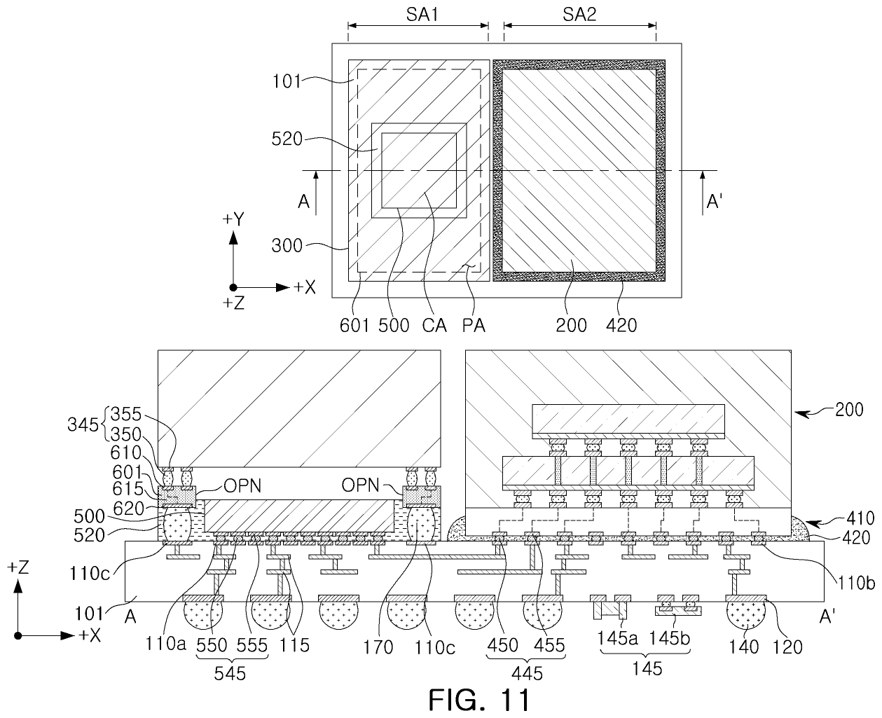

Referring to FIGS. 6 to 11, the method of manufacturing a semiconductor package according to example embodiments of the present disclosure may include: an operation of forming a first semiconductor chip 500 on a first region SA1 of a lower substrate 101 (see FIG. 6), an operation of forming electrical connectors 170 surrounding the first semiconductor chip 500 on the first region SA1 of the lower substrate 101, an operation of forming an upper substrate 601 formed on the first semiconductor chip 500 and the electrical connectors 170 and including a through-hole OPN exposing at least a portion of the first semiconductor chip 500 (see FIG. 7), an operation of forming an encapsulant 520 filling a space between the lower substrate 101 and the upper substrate 601 and encapsulating the electrical connectors 170 and a side surface of the first semiconductor chip 500 (see FIG. 8), an operation of forming a rewiring structure 410 and a second semiconductor chip 200 on a second region SA2 of the lower substrate 101 (see FIG. 9), an operation of forming an underfill material layer 420 surrounding a side surface of the rewiring structure 410 (see FIG. 10), and an operation of forming a third semiconductor chip 300 on the upper substrate 601 (see FIG. 11).

Referring to FIG. 6, the first semiconductor chip 500 may be formed on the first region SA1 of the lower substrate 101. In one example, the first semiconductor chip 500 may include a communication processor CP.

First upper pads 110a, 110b and 110c may be formed on an upper surface of the lower substrate 101. 1-1 upper pads 110a may be disposed on an upper surface of the first region SA1 of the lower substrate 101 overlapping the first semiconductor chip 500. 1-3 upper pads 110c may be disposed on the upper surface of the first region SA1 so as to surround the 1-1 upper pads 110a at the same level as the 1-1 upper pads 110a (e.g., surround the 1-1 upper pads 110a in a plan view). 1-2 upper pads 110b may be disposed at an upper surface of the second region SA2 of the lower substrate 101.

A first rewiring circuit 115 may be formed buried in the lower substrate 101.

Referring to FIG. 7, the electrical connectors 170 may be formed on the first region SA1 of the lower substrate 101. The electrical connectors 170 may surround the first semiconductor chip 500. The electrical connectors 170 may be formed on the 1-3 upper pads 110c and may be electrically connected to the first rewiring circuit 115. A second height H2 of the electrical connectors 170 in the vertical direction (+Z-direction) may be less than a first height H1 of the first semiconductor chip 500 relative to the lower substrate 101.

An upper substrate 601 may be formed on the electrical connectors 170 and the first semiconductor chip 500. The upper substrate 601 may include a through-hole OPN (or an opening region) exposing at least a portion of the first semiconductor chip 500. In one example, a width of the through-hole OPN of the upper substrate 601 in the horizontal direction (+X-direction) may be formed to be larger than a width of the first semiconductor chip 500. The through-hole OPN may accommodate a portion of the first semiconductor chip 500.

Second upper pads 610 may be formed at an upper surface of the upper substrate 601. Second lower pads 620 may be formed at a lower surface of the upper substrate 601. A second rewiring circuit 615 may be formed buried in the upper substrate 601. In one example, the second upper pads 610, the second lower pads 620 and the second rewiring circuit 615 may not overlap the first semiconductor chip 500 in the vertical direction.

Referring to FIG. 8, an encapsulant 520 may fill a space between the lower substrate 101 and the upper substrate 601 encapsulating a side surface of the electrical connectors 170 and a side surface of the first semiconductor chip 500. In one example, the encapsulant 520 may be formed in a transfer molding manner by injecting an encapsulant material in the first direction (+X-direction). In another example, the encapsulant 520 may be formed in a compression molding manner by injecting the encapsulant material in the vertical direction (+Z-direction).

In an example embodiment, third connection bumps 350 may be formed on the upper substrate 601. The third connection bumps 350 may be formed on the second upper pads 610 at the upper surface of the upper substrate 601.

Referring to FIG. 9, a rewiring structure 410 and a second semiconductor chip 200 may be sequentially formed on the second region SA2 of the lower substrate 101.

Second connection patterns 445 which include second connection bumps 450 and second connection pads 455 may be formed on the 1-1 upper pads 110a. The second connection bumps 450 and the second connection pads 455 may be sequentially formed on the 1-1 upper pads 110a.

The rewiring structure 410 may be formed on the second connection patterns 445. The second semiconductor chip 200 may be formed on the rewiring structure 410. In one example, the second semiconductor chip 200 may be a logic chip, a processor chip, or a controller chip.

Referring to FIG. 10, an underfill material layer 420 may be formed surrounding a side surface of the rewiring structure 410. In a process of forming the underfill material layer 420, the encapsulant 520 encapsulating the electrical connector 170 and the side surface of the first semiconductor chip 500 may function as a guide member to prevent the underfill material layer 420 from flowing into spaces other than a space adjacent to the side surface of the rewiring structure 410.

Referring to FIG. 11, a third semiconductor chip 300 may be formed on the upper substrate 601. In one example, the third semiconductor chip 300 may cover the first region SA1 of the lower substrate 101. In one example, the third semiconductor chip 300 may include a memory chip.

The method of manufacturing a semiconductor package according to example embodiments of the present disclosure may further include an operation of forming lower connection bumps 140 and/or passive elements 145 on a lower surface of the lower substrate 101.

The method of manufacturing a semiconductor package according to example embodiments of the present disclosure may form the first and second semiconductor chips 500 and 200 spaced apart from each other in the horizontal direction, may expose at least a portion of the first semiconductor chip 500 on the first semiconductor chip 500, and form the upper substrate 601 on which the third semiconductor chip 300 is mounted, thereby providing a semiconductor package that may effectively dissipate heat generated in the first semiconductor chip 500.

While example embodiments have been illustrated and described above, it will be apparent to those skilled in the art that modifications and variations could be made within a scope not departing from the spirit and region of the present disclosure as defined by the appended claims.

What is claimed is:

1. A semiconductor package comprising:
a lower substrate including a lower wiring layer;
an upper substrate disposed on the lower substrate and including an upper wiring layer;
a first semiconductor chip disposed having a lower surface between an upper surface of the lower substrate and a lower surface of the upper substrate and electrically connected to the lower wiring layer;
a second semiconductor chip disposed on the lower substrate and spaced apart from the first semiconductor chip in a first direction and electrically connected to the lower wiring layer; and
a third semiconductor chip disposed on the upper substrate and electrically connected to the upper wiring layer,
wherein the upper substrate has a through-hole exposing at least a portion of the first semiconductor chip.

2. The semiconductor package of claim 1, wherein the upper substrate includes a central region corresponding to the through-hole and a peripheral region surrounding the central region and that includes the upper wiring layer.

3. The semiconductor package of claim 2, wherein the first semiconductor chip does not overlap the peripheral region of the upper substrate in a vertical direction.

4. The semiconductor package of claim 2, wherein a width of the through-hole in the first direction is greater than a width of the first semiconductor chip in the first direction.

5. The semiconductor package of claim 1, further comprising:
an electrical connector disposed between the lower substrate and the upper substrate and electrically connecting the lower wiring layer and the upper wiring layer.

6. The semiconductor package of claim 5, wherein a first height of an upper surface of the first semiconductor chip in a vertical direction is higher than a second height of an upper surface of the electrical connector in the vertical direction relative to the lower substrate.

7. The semiconductor package of claim 5, further comprising:
an encapsulant filling a space between the lower substrate and the upper substrate and encapsulating the electrical connector and a side surface of the first semiconductor chip.

8. The semiconductor package of claim 7, wherein a portion of the first semiconductor chip is disposed in the through-hole of the upper substrate.

9. The semiconductor package of claim 8, wherein the encapsulant partially fills the through-hole.

10. The semiconductor package of claim 1, further comprising:
a connection pattern disposed between the third semiconductor chip and the upper substrate and electrically connecting the third semiconductor chip and the upper wiring layer,
wherein the connection pattern does not overlap the first semiconductor chip in a vertical direction.

11. The semiconductor package of claim 1, further comprising:
a rewiring structure disposed between the lower substrate and the second semiconductor chip and including a plurality of wiring layers; and
an underfill material layer surrounding a side surface of the rewiring structure.

12. The semiconductor package of claim 11, further comprising:
a first connection pattern disposed between the first semiconductor chip and the lower substrate; and
a second connection pattern disposed between the rewiring structure and the lower substrate,
wherein the first connection pattern and the second connection pattern are disposed at the same level.

13. The semiconductor package of claim 1, wherein the upper substrate has a ring shape.

14. The semiconductor package of claim 1, wherein the first semiconductor chip comprises a communication processor (CP),
the second semiconductor chip comprises an application processor (AP), and
the third semiconductor chip comprises a memory chip.

15. A semiconductor package comprising:
a lower substrate including a first region and a second region spaced apart from the first region in a first direction, and including a lower wiring layer;
a first semiconductor chip disposed on the first region and electrically connected to the lower wiring layer;
a second semiconductor chip disposed on the second region and electrically connected to the lower wiring layer;
an upper substrate including a through-hole exposing at least a portion of an upper surface of the first semiconductor chip disposed on the first region, and an upper wiring layer; and
a third semiconductor chip disposed on the upper substrate and electrically connected to the upper wiring layer.

16. The semiconductor package of claim 15, further comprising:
an electrical connector disposed between the lower substrate and the upper substrate and electrically connecting the lower wiring layer and the upper wiring layer,
wherein the electrical connector is disposed at the same level as the first semiconductor chip and surrounds the first semiconductor chip.

17. The semiconductor package of claim 16, further comprising:
a third connection pattern disposed between the upper substrate and the third semiconductor chip and electrically connecting the third semiconductor chip and the upper wiring layer,
wherein the electrical connector and the third connection pattern overlap each other in a vertical direction.

18. The semiconductor package of claim 16, wherein an upper surface of the first semiconductor chip is disposed at the same level as an upper surface of the upper substrate.

19. A semiconductor package comprising:
a lower substrate including a lower wiring layer;
an upper substrate disposed on the lower substrate and including an upper wiring layer;
a plurality of electrical connectors disposed between the lower substrate and the upper substrate and electrically connecting the lower wiring layer and the upper wiring layer;
a first semiconductor chip disposed at the same level as the plurality of electrical connectors, surrounded by the plurality of electrical connectors, and electrically connected to the lower wiring layer;
a second semiconductor chip disposed on the lower substrate to be spaced apart from the first semiconductor chip in a first direction and electrically connected to the lower wiring layer; and
a third semiconductor chip disposed on the upper substrate and electrically connected to the upper wiring layer,
wherein an upper surface of the first semiconductor chip is at least partially exposed through an opening region of the upper substrate.

20. The semiconductor package of claim 19, wherein a portion of the first semiconductor chip is disposed in the opening region.
